(19) United States
(12) Patent Application Publication
(10) Pub. No.: US 2025/0120043 A1
(43) Pub. Date: Apr. 10, 2025

(54) IMMERSION COOLING EQUIPMENT

(71) Applicant: Wiwynn Corporation, New Taipei City (TW)

(72) Inventors: You-Cheng Wang, New Taipei City (TW); Kang-Bin Mah, New Taipei City (TW); Tzu-Hsuan Feng, New Taipei City (TW); Hsien-Chieh Hsieh, New Taipei City (TW)

(73) Assignee: Wiwynn Corporation, New Taipei City (TW)

(21) Appl. No.: 18/656,514

(22) Filed: May 6, 2024

(30) Foreign Application Priority Data
Oct. 6, 2023 (TW) 112138407

(51) Int. Cl. H05K 7/20

(52) U.S. Cl. CPC H05K 7/20272; H05K 7/20236; H05K 7/20781

(57) ABSTRACT

An immersion cooling equipment is configured to cool an electronic device. The immersion cooling equipment includes a tank and a hollow fluid blocking member. The tank is filled with coolant. The electronic device is disposed in the tank and immersed in the coolant. The hollow fluid blocking member is replaceably placed in the tank to be immersed in the coolant. During a process of placing the hollow fluid blocking member into the tank, a portion of the coolant in the tank flows into the hollow fluid blocking member, and during a process of detaching the hollow fluid blocking member from the tank, the coolant in the hollow fluid blocking member flows out of the hollow fluid blocking member and flows back to the tank.

### CROSS-REFERENCE TO RELATED APPLICATION

This application claims the priority benefit of Taiwan application serial no. 112138407, filed on Oct. 6, 2023. The entirety of the above-mentioned patent application is hereby incorporated by reference herein and made a part of this specification.

### BACKGROUND

### Technical Field

The disclosure relates to an immersion cooling equipment, and more particularly, to an immersion cooling equipment having a hollow fluid blocking member.

### Description of Related Art

In order to improve an issue of heat dissipation of an electronic device, one of the

methods is to immerse the electronic device in a tank filled with coolant for heat dissipation. However, when the space in the tank is not fully utilized (for example, a sufficient number or volume of electronic devices is not disposed in the tank), the unused space will become an area with smaller flow resistance (that is, the flow resistance where the electronic device is disposed is greater than the flow resistance where the electronic device is not disposed), causing most of the coolant to be directed to the unused space. This will reduce a flow rate of the coolant through the electronic device, which is not conducive to the heat dissipation.

Based on the above, how to appropriately and correspondingly adjust the tank that is not fully loaded with the electronic devices while maintaining basic heat dissipation performance is actually a topic for relevant technical personnel to ponder and solve.

### SUMMARY

An immersion cooling equipment in the disclosure is configured to cool an electronic device. The immersion cooling equipment includes a tank and a hollow fluid blocking member. The tank is filled with coolant. The electronic device is disposed in the tank and immersed in the coolant. The hollow fluid blocking member is replaceable placed in the tank to be immersed in the coolant. During a process of placing the hollow fluid blocking member into the tank, a portion of the coolant in the tank flows into the hollow fluid blocking member, and during a process of detaching the hollow fluid blocking member from the tank, the coolant in the hollow fluid blocking member flows out of the hollow fluid blocking member and flows back to the tank.

### BRIEF DESCRIPTION OF THE DRAWINGS

FIG. 1 is a schematic view of an immersion cooling equipment according to an embodiment of the disclosure.

FIGS. 2A to 2C are schematic views of an operation process between a hollow fluid blocking member and a tank.

FIGS. 3A to 3C are schematic views of an operation process between a hollow fluid blocking member and a tank according to another embodiment of the disclosure.

FIG. 4 is a schematic partial view of a hollow fluid blocking member according to another embodiment of the disclosure.

FIGS. 5A to 5C are schematic views of an operation process between the hollow fluid blocking member and a tank in FIG. 4.

### DETAILED DESCRIPTION OF DISCLOSED EMBODIMENTS

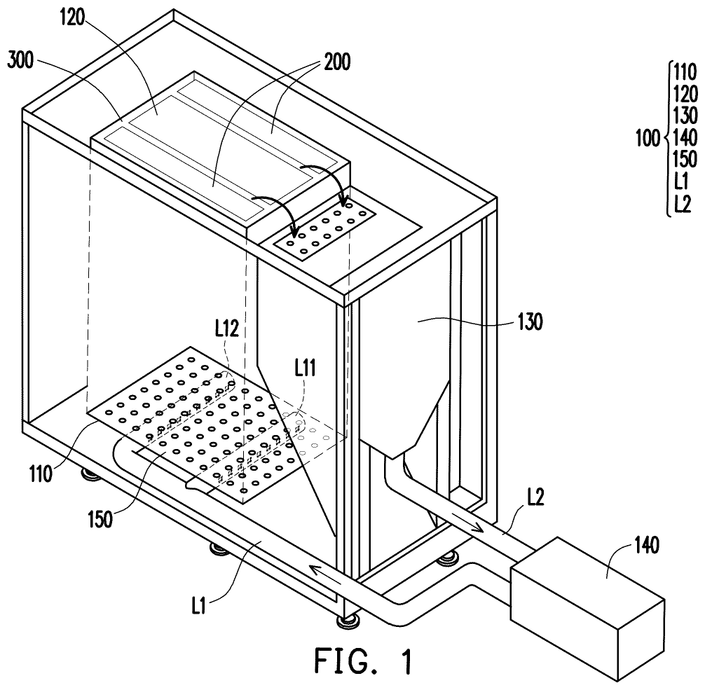

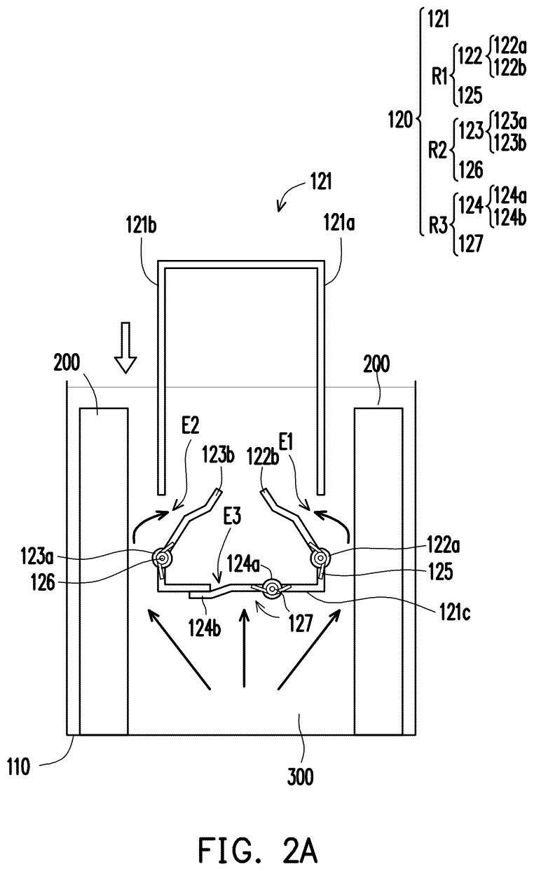

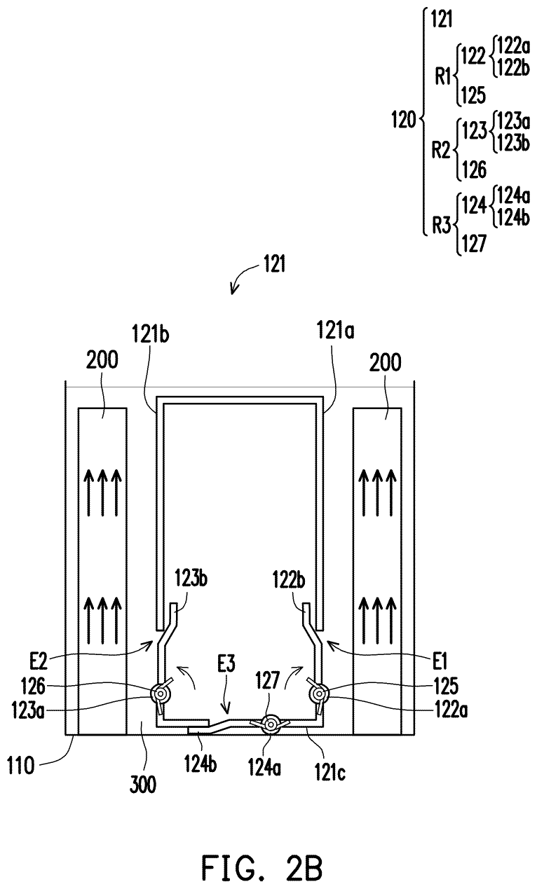

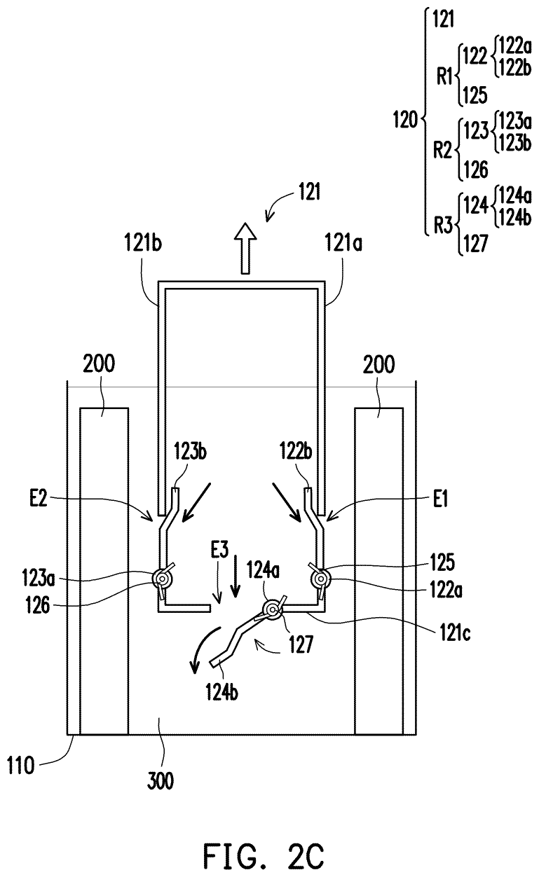

FIG. 1 is a schematic view of an immersion cooling equipment according to an embodiment of the disclosure. FIGS. 2A to 2C are schematic views of an operation process between a hollow fluid blocking member and a tank. Referring to FIGS. 1 and 2A first, in this embodiment, an immersion cooling equipment 100 may be configured to cool an electronic device 200, which includes a tank 110, a hollow fluid blocking member 120, a secondary tank 130, pipe lines L1 and L2, a cooling distribution unit (CDU) 140, and a rectification mesh plate 150. The tank 110 is adapted to be filled with coolant 300. The electronic device 200, such as a server device, is adapted to be disposed in the tank 110 and immersed in the coolant 300, so that the coolant 300 may absorb heat for the electronic device 200. In this embodiment, the immersion cooling equipment 100 is, for example, a single-phase immersion cooling equipment, and the coolant 300 thereof has characteristics of a high boiling point, non-conductivity, and a high flash point to facilitate heat transfer and avoid volatilization.

As shown in FIG. 1, the CDU 140 is connected to the tank 110 through the pipe line L1 and connected to the secondary tank 130 through the pipe line L2, and is configured to promote fluid circulation in the immersion cooling equipment 100. Furthermore, the coolant 300 is supplied into the tank 110 along with the pipe line L1 and branches L11 and L12 thereof, and flows upward through the rectification mesh plate 150 and flows through the electronic device 200 to absorb the heat generated by the electronic device 200. The coolant 300 after absorbing the heat will overflow to the secondary tank 130, and is transmitted back to the CDU 140 through the pipe line L2, so as to perform heat exchange on the coolant 300, thereby dissipating the heat and cooling the coolant 300. After that, the coolant 300 may be transmitted to the tank 110 through the pipe line L1 and the branches L11 and L12 for the next circulation.

Referring to FIGS. 2A to 2C together, the hollow fluid blocking member 120 in this embodiment is substantially formed by a hollow body 121 and a first movable gate R1, a second movable gate R2, and a third movable gate R3. The hollow body 121 has three openings E1, E2, and E3, and the first movable gate R1, the second movable gate R2, and the third movable gate R3 respectively correspond to the three openings E1, E2, and E3, and provide opening and closing effects to the three openings E1 to E3.

Specifically, the first movable gate R1 and the second movable gate R2 are respectively located on two opposite side plates 121a and 121b of the hollow fluid blocking member 120 to open and close the openings E1 and E2, and the third movable gate R3 is located on a base plate 121c of the hollow fluid blocking member 120 to open and close the opening E3. The first movable gate R1 and the second movable gate R2 may only be opened from an outside to an inside, and the third movable gate R3 may only be opened from the inside to the outside. The hollow fluid blocking member 120 is replaceably placed in the tank 110 to be immersed in the coolant 300. Furthermore, during a process of placing the hollow fluid blocking member 120 into the tank 110, a portion of the coolant 300 in the tank 110 flows into the hollow fluid blocking member 120 through the first movable gate R1 and the second movable gate R2, but does not flow into the hollow fluid blocking member 120 through the third movable gate R3. On the other hand, during a process of detaching the hollow fluid blocking member 120 from the tank 110, as a liquid pressure of the coolant 300 on the third movable gate R3 gradually decreases, the coolant 300 in the hollow fluid blocking member 120 drives the third movable gate R3 to open due to a weight thereof, so that the coolant 300 flows back to the tank 110 through the third movable gate R3, but does not flow out of the hollow fluid blocking member 120 through the first movable gate R1 and the second movable gate R2.

In this embodiment, the first movable gate R1 includes a first door plate 122. A shaft end 122a of the first door plate 122 is pivotally connected to the side plate 121a, and an end 122b of the first door plate 122, relative to the shaft end 122a, may be opened and closed against an inner wall of the side plate 121a. Furthermore, the first movable gate R1 further includes a first torsion spring 125 disposed on the shaft end 122a of the first door plate 122 and abutting between the first door plate 122 and the side plate 121a. The first torsion spring 125 constantly drives the first door plate 122 to be closed on the inner wall of the side plate 121a. Similarly, the second movable gate R2 includes a second door plate 123. A shaft end 123a of the second door plate 123 is pivotally connected to the side plate 121b, and an end 123b of the second door plate 123, relative to the shaft end 123a, may be opened and closed against an inner wall of the side plate 121b. Furthermore, the second movable gate R2 further includes a second torsion spring 126 disposed on the shaft end 123a of the second door plate 123 and abutting between the second door plate 123 and the side plate 121b. The second torsion spring 126 constantly drives the second door plate 123 to be closed on the inner wall of the side plate 121b.

Furthermore, the third movable gate R3 in this embodiment includes a third door plate 124 and a third torsion spring 127. A shaft end 124a of the third door plate 124 is pivotally connected to the base plate 121c, and the third torsion spring 127 is disposed on the shaft end 124a and abuts between the third door plate 124 and the base plate 121c. An end 124b of the third door plate 124, relative to the shaft end 124a, may be opened and closed against an outer wall of the base plate 121c. The third torsion spring 127 constantly drives the third door plate 124 to be closed on the outer wall of the base plate 121c.

As mentioned above, a corresponding configuration of the first movable gate R1, the second movable gate R2, the third movable gate R3, and the hollow body 121 may cause the hollow fluid blocking member 120 to generate corresponding changes during an operation process in FIGS. 2A to 2C. When a user places the hollow fluid blocking member 120 into the coolant 300 to an appropriate depth, the liquid pressure of the coolant 300 may overcome torsion force of the first torsion spring 125 and the second torsion spring 126, thereby driving the first door plate 122 and the second door plate 123 to open from the outside to the inside respectively, so that a portion of the coolant 300 in the tank 110 flows into the hollow body 121 through the openings E1 and E2 respectively. At this time, for the third movable gate R3, since the third door plate 124 may only be opened from the inside to the outside, and it is continuously subjected to the pressure of the coolant 300, a sum of the torsion force of the third torsion spring 127 and the liquid pressure of the coolant 300 in the tank 110 on the third door plate 124 is still greater than the liquid pressure of the coolant 300 flowing into the hollow body 121 on the third door plate 124. As a result, the third door plate 124 may not be opened relative to the base plate 121c. Therefore, during the process from FIGS. 2A to 2B, a portion of the coolant 300 in the tank 110 may only continue to flow into the hollow body 121 through the first movable gate R1 and the second movable gate R2, while the third movable gate R3 is continuously closed (to prevent the coolant 300 from flowing out of the hollow body 121) until the coolant 300 gradually fills the hollow body 121. In addition, while the hollow body 121 is filled, the third movable gate R3 also leans against a bottom of the tank 110, as shown in FIG. 2B.

In this way, the hollow fluid blocking member 120 may be firmly seated at the bottom of the tank 110. More importantly, when the coolant 300 is supplied from the pipe line L1 to the tank 110 as mentioned above, due to obstruction of the hollow fluid blocking member 120, the coolant 300 will flow to the electronic devices 200 on two sides. In other words, when the tank 110 is not fully loaded with the electronic devices 200, the hollow fluid blocking member 120 may be used to fill unused space in the tank 110 to control a flow direction of the coolant 300 such that it flows through the electronic device 200, which not only improves heat dissipation efficiency, but also balances internal and external pressures of the tank 110.

Next, during the operation process from FIGS. 2B to 2C, that is, during a process of moving the hollow fluid blocking member 120 away from the tank 110, the weight of the coolant 300 in the hollow body 121 is greater than the torsion force of the third torsion spring 127 and the liquid pressure of the coolant 300 in the tank 110 on the third door plate 124. Therefore, as the user moves the hollow fluid blocking member 120 away from the bottom of the tank 110, the coolant 300 in the hollow body 121 will drive the third door plate 124 to be unfolded, so that the coolant 300 flows into the tank 110 from the hollow body 121. In this way, since the coolant 300 may flow out of the hollow body 121 during the process of moving the hollow fluid blocking member 120 away from the tank 110, a level height of the coolant 300 in the tank 110 will not easily change significantly, which may avoid affecting the heat dissipation effect due to the level height of the coolant 300 being lower than a height of the electronic device 200. In addition, the weight of the hollow fluid blocking member 120 may also be effectively reduced, thereby reducing the force required by the user to move the hollow fluid blocking member 120 away, which has an obvious labor-saving effect and is conducive to replacement of the hollow fluid blocking member 120.

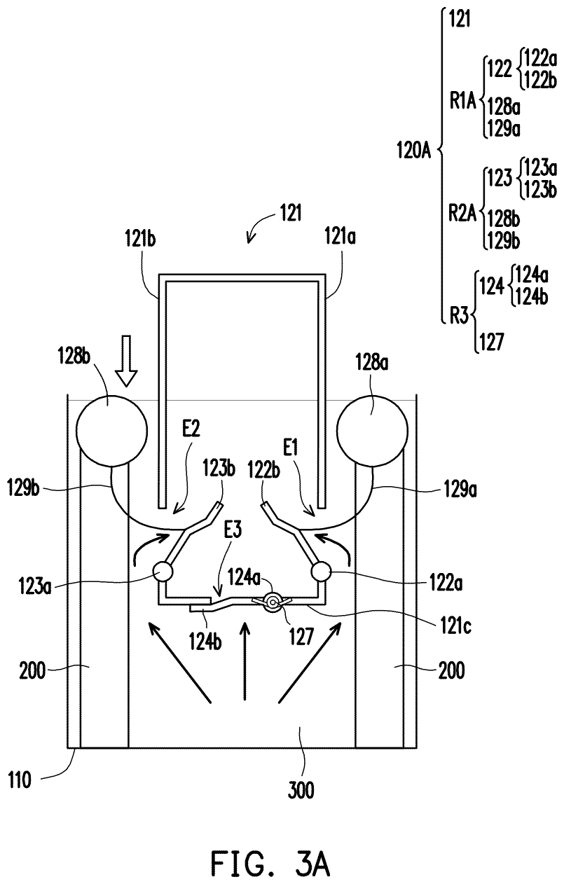

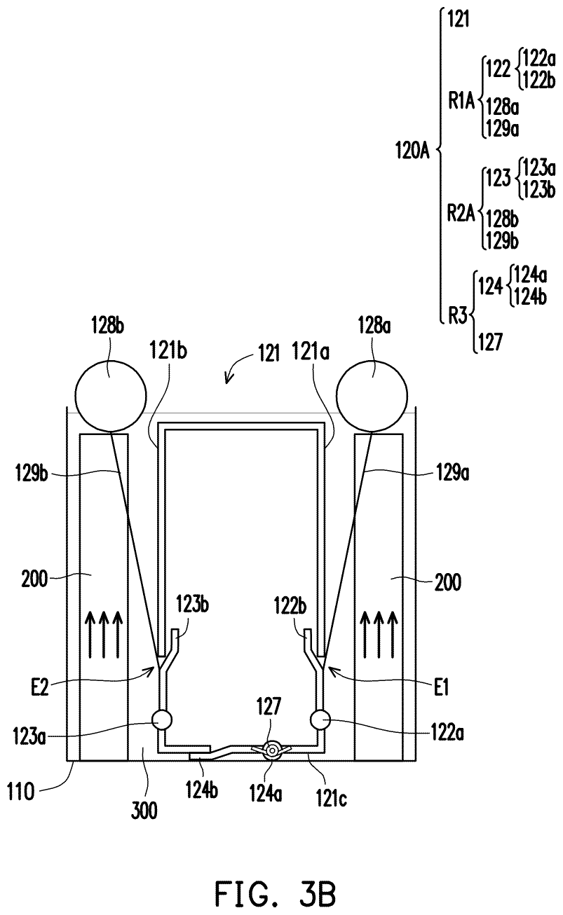

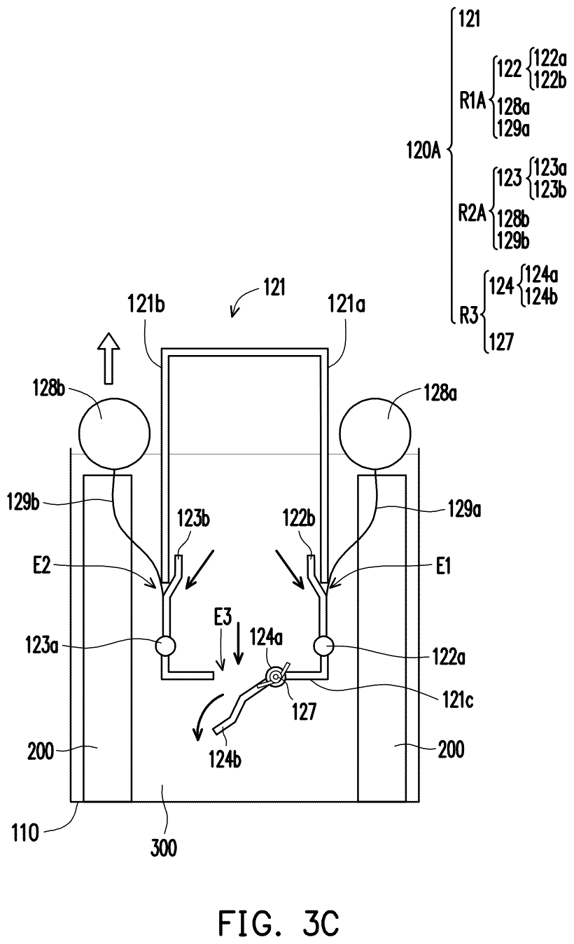

FIGS. 3A to 3C are schematic views of an operation process between a hollow fluid blocking member and a tank according to another embodiment of the disclosure. Referring to

FIGS. 3A to 3C together, a difference from the previous embodiment is that in a hollow fluid blocking member 120A in this embodiment, a first movable gate R1A includes the first door plate 122, a first floating body 128a, and a first cord 129a, and a second movable gate R2A includes the second door plate 123, a second floating body 128b, and a second cord 129b. The shaft end 122a of the first door plate 122 is pivotally connected to the side plate 121a, and the end 122b of the first door plate 122, relative to the shaft end 122a, may be opened and closed against the inner wall of the side plate 121a. The first floating body 128a is connected to the first door plate 122 through the first cord 129a to constantly drive the first door plate 122 to be closed on the inner wall of the side plate 121a, and a density of the first floating body 128a is less than a density of the coolant 300. Similarly, the shaft end 123a of the second door plate 123 is pivotally connected to the side plate 121b, and the end 123b of the second door plate 123, relative to the shaft end 123a, may be opened and closed against the inner wall of the side plate 121b. The second floating body 128b is connected to the second door plate 123 through the second cord 129b to constantly drive the second door plate 123 to be closed on the inner wall of the side plate 121b, and a density of the second floating body 128b is less than the density of the coolant 300. In this way, as the hollow fluid blocking member 120A enters the coolant 300 more deeply, buoyancy force received by the first floating body 128a and the second floating body 128b will be greater until the first door plate 122 and the second door plate 123 may be driven to close as shown in FIG. 3B.

Next, the operation process from FIGS. 3B to 3C is the same as the above process from FIGS. 2B to 2C. That is, as the user moves the hollow fluid blocking member 120A away from the bottom of the tank 110, the coolant 300 in the hollow body 121 drives the third movable gate R3 to open, so that the coolant 300 in the hollow body 121 flows into the tank 110. In addition, in this embodiment, a position where the first cord 129a is connected to the first door plate 122 and a position where the second cord 129b is connected to the second door plate 123 are not limited, which may depend on actual design requirements.

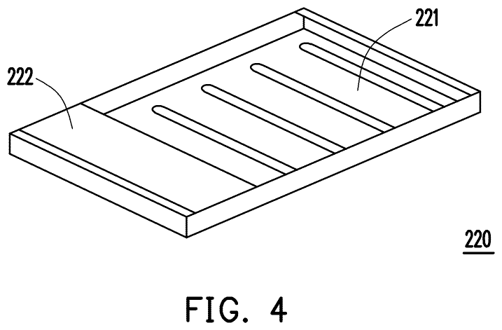

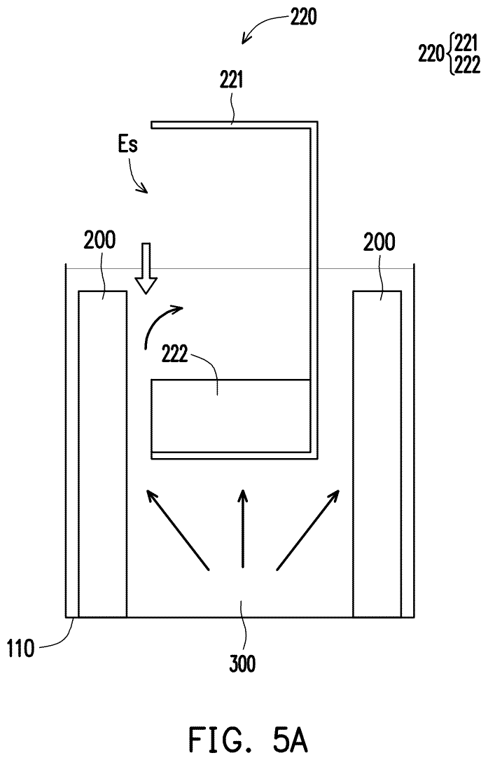

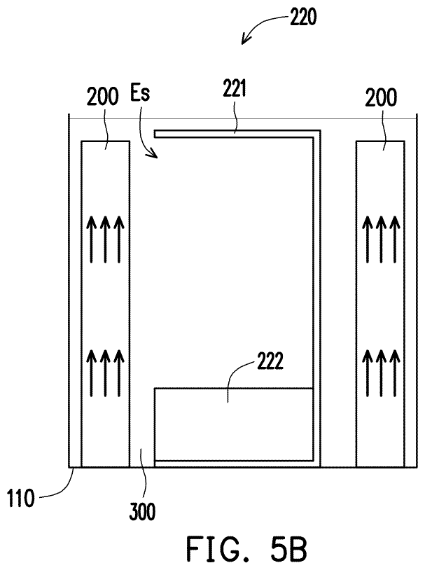

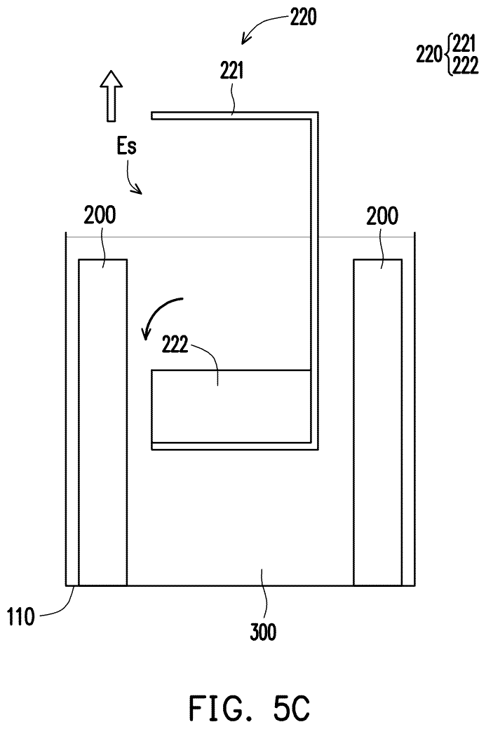

FIG. 4 is a schematic partial view of a hollow fluid blocking member according to another embodiment of the disclosure. FIGS. 5A to 5C are schematic views of an operation process between the hollow fluid blocking member in FIG. 4 and a tank. Referring to FIGS. 4 and 5A first, a difference from the previous embodiment is that a hollow body 221 of a hollow fluid blocking member 220 has a chassis structure with a single-side opening Es, and further includes a counterweight block 222 disposed in the chassis structure and located on a base plate of the chassis structure. In this embodiment, a material of the hollow body 221 is, for example, iron, steel, or stainless steel, and a material of the counterweight block 222 is, for example, bakelite. Furthermore, in this embodiment a position of the counterweight block 222 disposed on the base plate is not limited, and a volume size and quantity of the counterweight block 222 is also not limited, which may depend on the actual design requirements.

Referring to FIGS. 5A to 5C, when the hollow fluid blocking member 220 is placed in the tank 110, the counterweight block 222 may assist the hollow fluid blocking member 220 to enter the coolant 300. The coolant 300 may also quickly flow into the hollow body 221 from the single-side opening Es to fill the hollow body 221, and while the hollow body 221 is filled, the hollow body 221 also leans against the bottom of the tank 110. On the contrary, when the hollow fluid blocking member 220 is to be moved away from the tank 110, the coolant 300 in the hollow body 221 will also quickly flow out of the hollow body 221 through the single-side opening Es and flow into the tank 110.

It should be noted that in the disclosure, a position and quantity of the electronic device

200 disposed in the tank 110 are not limited, and volume size and quantities of the hollow fluid blocking members 120, 120A, and 220 are also not limited, which may depend on the actual design requirements.

Based on the above, in the above embodiments of the disclosure, the immersion cooling equipment fills the unused space in the tank through the hollow fluid blocking member, thereby improving the heat dissipation effect of the coolant on the electronic device.

In brief, the hollow fluid blocking member may enable the coolant in the tank to flow into the hollow body when it is moved into the tank, thereby enabling the hollow fluid blocking member to be stably disposed in the tank. In this way, the coolant supplied to the tank will be blocked by the hollow fluid blocking member and directed to the position of the electronic device, thus helping to dissipate the heat from the electronic device. In addition, the hollow fluid blocking member may also enable the coolant in the hollow body to flow into the tank when it is moved out of the tank. Therefore, the level height of the coolant in the tank does not easily change significantly, which may also effectively reduce the weight of the hollow fluid blocking member and provide the labor-saving effect.

What is claimed is:

1. An immersion cooling equipment configured to cool an electronic device, wherein the immersion cooling equipment comprises:
a tank filled with coolant, wherein the electronic device is disposed in the tank and immersed in the coolant; and
a hollow fluid blocking member replaceably placed in the tank to be immersed in the coolant, wherein during a process of placing the hollow fluid blocking member into the tank, a portion of the coolant in the tank flows into the hollow fluid blocking member, and during a process of detaching the hollow fluid blocking member from the tank, the coolant in the hollow fluid blocking member flows out of the hollow fluid blocking member and flows back to the tank.

2. The immersion cooling equipment according to claim 1, wherein the hollow fluid blocking member has a first movable gate, a second movable gate, and a third movable gate, the first movable gate and the second movable gate are respectively located on two opposite side plates of the hollow fluid blocking member, and the third movable gate is located on a base plate of the hollow fluid blocking member.

3. The immersion cooling equipment according to claim 2, wherein the first movable gate and the second movable gate are only be opened from an outside to an inside, and the third movable gate is only opened from the inside to the outside.

4. The immersion cooling equipment according to claim 2, wherein during the process of placing the hollow fluid blocking member into the tank, the portion of the coolant in the tank flows into the hollow fluid blocking member through the first movable gate and the second movable gate, and during the process of detaching the hollow fluid blocking member from the tank, the coolant in the hollow fluid blocking member flows back to the tank through the third movable gate.

5. The immersion cooling equipment according to claim 2, wherein the first movable gate comprises a first door plate, a shaft end of the first door plate is pivotally connected to the side plate, and an end of the first door plate, relative to the shaft end, is opened and closed against an inner wall of the side plate.

6. The immersion cooling equipment according to claim 5, wherein the first movable gate further comprises a first torsion spring disposed on the shaft end of the first door plate and abutting between the first door plate and the side plate, and the first torsion spring constantly drives the first door plate to be closed on the side plate.

7. The immersion cooling equipment according to claim 5, wherein the first movable gate further comprises a first floating body and a first cord, the first floating body is connected to the first door plate through the first cord, and a density of the first floating body is less than a density of the coolant.

8. The immersion cooling equipment according to claim 2, wherein the second movable gate comprises a second door plate, a shaft end of the second door plate is pivotally connected to the side plate, and an end of the second door plate, relative to the shaft end, is opened and closed against an inner wall of the side plate.

9. The immersion cooling equipment according to claim 8, wherein the second movable gate further comprises a second torsion spring disposed on the shaft end of the second door plate and abutting between the second door plate and the side plate, and the second torsion spring constantly drives the second door plate to be closed on the side plate.

10. The immersion cooling equipment according to claim 8, wherein the second movable gate further comprises a second floating body and a second cord, the second floating body is connected to the second door plate through the second cord, and a density of the second floating body is less than a density of the coolant.

11. The immersion cooling equipment according to claim 2, wherein the third movable gate comprises a third door plate and a third torsion spring, a shaft end of the third door plate is pivotally connected to the base plate, the third torsion spring is disposed on the shaft end and abuts between the third door plate and the base plate, and an end of the third door plate, relative to the shaft end, is opened and closed against an outer wall of the base plate.

12. The immersion cooling equipment according to claim 1, wherein the hollow fluid blocking member is a chassis structure with a single-side opening.

13. The immersion cooling equipment according to claim 12, wherein the hollow fluid blocking member further comprises a counterweight block disposed in the chassis structure and located on a base plate of the chassis structure.

14. The immersion cooling equipment according to claim 1, wherein the hollow fluid blocking member is configured to fill an unused space in the tank.

15. The immersion cooling equipment according to claim 1, wherein the immersion cooling equipment is a single-phase immersion cooling equipment.
